(19) United States
(12) Patent Application Publication
(10) Pub. No.: US 2018/0165996 A1
(43) Pub. Date: Jun. 14, 2018

(54) FLEXIBLE ELECTRONIC DEVICE AND METHOD FOR MANUFACTURING FLEXIBLE ELECTRONIC DEVICE

(71) Applicant: Sharp Kabushiki Kaisha, Sakai City, Osaka (JP)

(72) Inventors: Takashi OCHI, Sakai City (JP); Yuki YASUDA, Sakai City (JP); Shoji OKAZAKI, Sakai City (JP); Hiroshi SUGIMOTO, Sakai City (JP); Kenji MISONO, Sakai City (JP); Masahiro HASEGAWA, Sakai City (JP); Noriko WATANABE, Sakai City (JP); Kazuhiko TSUDA, Sakai City (JP)

(21) Appl. No.: 15/735,251

(22) PCT Filed: Jun. 13, 2016
(86) PCT No.: PCT/JP2016/067581

§ 371 Date: Dec. 11, 2017

(30) Foreign Application Priority Data
Jun. 18, 2015 (JP) 2015-123119

(51) Int. Cl. G09F 9/30; H01L 51/50; H05B 33/04; H05B 33/14

(52) U.S. Cl. CPC G09F 9/30; H05B 33/14; H05B 33/04; H01L 51/50

(57) ABSTRACT

The present invention prevents an advance of a crack in a covering layer, without exposing a support. In a region between an edge part of a moistureproof layer (12) and a display region (2), wavy recessed patterns (7a, 7b, and 7c) are continuously or discontinuously provided so to connect one end of the moistureproof layer (12) and another end of the moistureproof layer (12). Each of the wavy recessed patterns (7a, 7b, and 7c) is recessed and is configured to change a direction in which a crack having appeared in the edge part of the moistureproof layer (12) advances.

### TECHNICAL FIELD

The present invention relates to a flexible electronic device and a method of producing the flexible electronic device.

### BACKGROUND ART

A flexible electronic device includes a flexible circuit substrate in which a circuit mainly including various elements and wires is provided on a flexible support covered with a covering layer. The covering layer is constituted by an inorganic insulating layer, and is referred to as a moistureproof layer, a protecting layer, a base insulating layer, or the like.

Use of a flexible electronic device as an integrated circuit (IC) tag, an IC card, electronic paper, a flexible display device, or the like is under consideration from the viewpoint that the flexible electronic device is thin, light, and flexible.

In particular, a so-called flexible display whose display part is flexibly deformable is drawing attention as a thin, light, and bendable display.

A flexible display includes an electro-optic element, other circuits that drive the electro-optic element, a support which supports those circuits, and various functional layers. The flexible display has a structure in which the electro-optic element and the circuits are sandwiched by the support and the various functional layers.

Examples of the electro-optic element include a liquid crystal layer and an electro luminescence (hereinafter referred to as “EL”) element, which is a light-emitting element in which electroluminescence of a light-emitting material is used. Examples of the support include a flexible film such as a polyimide film, and a flexible substrate such as a polyimide substrate. Examples of the various functional layers include a flexible film such as a polyimide film, a flexible substrate such as a polyimide substrate, a touch panel, a hard coating, and a polarizing plate.

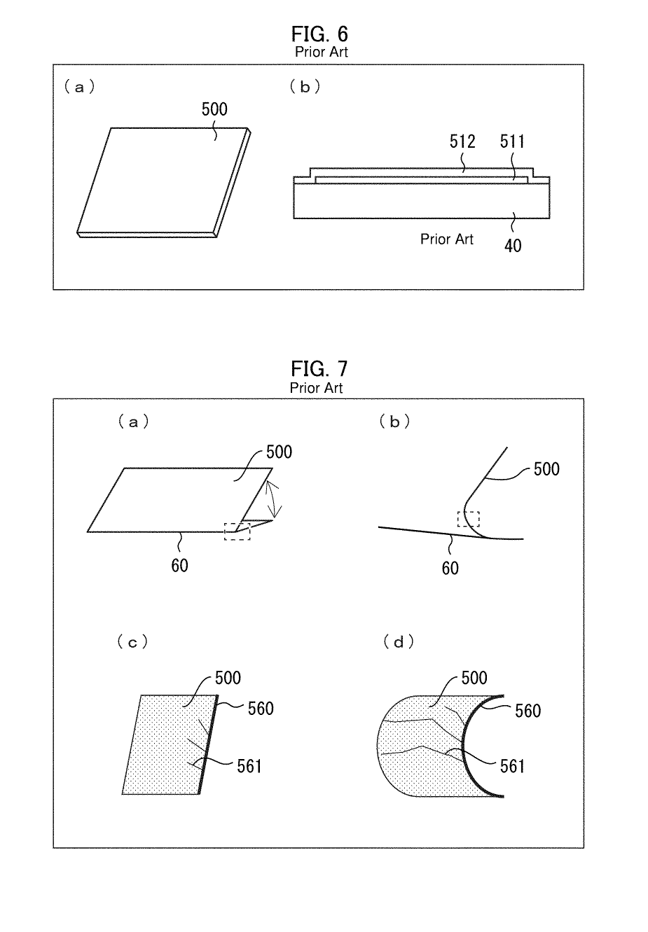

(a) of FIG. 6 is a perspective view illustrating a conventional flexible electronic device. (b) of FIG. 6 is a cross-sectional view illustrating a configuration of a main part of the conventional flexible electronic device from which a carrier substrate has not been peeled off.

A process for producing a flexible electronic device 500 is carried out as illustrated in (b) of FIG. 6. Specifically, for example, a support 511, which is constituted by a flexible film such as a polyimide film, is formed on a carrier substrate 40 via a release layer (not illustrated). Then, a covering layer 512, which is constituted by an inorganic insulating layer and is referred to as a moistureproof layer, a protecting layer, or a base insulating layer, is formed on the support 511. On the covering layer 512, a circuit mainly including various elements and wires is provided. Finally, the carrier substrate 40 and the release layer are peeled off from the support. Thus, a bendable flexible electronic device 500 can be obtained in which the circuit mainly including various elements and wires is provided on a flexible film such as a polyimide film.

(a) of FIG. 7 is a perspective view illustrating a state in which a conventional flexible electronic device is bent. (b) of FIG. 7 is an enlarged side view illustrating an arrangement of a surrounding area of a broken-line box of (a) of FIG. 7. (c) of FIG. 7 is a perspective view of a main part of the flexible electronic device, the perspective view illustrating a crack having appeared in the broken-line box of each of (a) and (b) of FIG. 7. (d) of FIG. 7 is a perspective view of the main part of the flexible electronic device, the perspective view illustrating how the crack advances in (a) and (b) of FIG. 7 in a case where the flexible electronic device is bent.

In a mass production process, a plurality of flexible electronic devices 500 are formed on the carrier substrate 40, the carrier substrate 40 is peeled off, and then the plurality of flexible electronic devices 500 are divided into separate flexible electronic devices 500. During the division of the plurality of flexible electronic devices 500, a minute crack 561 appears in an edge part 560 of each of the flexible electronic devices 500 (see (c) of FIG. 7).

In a case where a flexible electronic device 500 is bent as illustrated in (a) of FIG. 7, the minute crack 561 which has appeared in the edge part 560 starts expanding and advances towards a center of the flexible electronic device 500 (see (d) of FIG. 7). Consequently, the crack 561 may extend to a circuit formation region (i.e., a region in which a circuit is provided) of the flexible electronic device.

A flexible electronic device thus has a problem of an advance of a crack which advance is caused by bending of the flexible electronic device. In particular, a crack frequently appears and easily propagates in an inorganic insulating layer having a high Young's modulus. A crack having appeared at one spot easily propagates through an inorganic insulating layer and spreads over an entire flexible electronic device (see, for example, Patent Literature 1).

Patent Literature 1 discloses the following. Specifically, a flexible substrate is used as a carrier substrate, a separating layer is formed as a release layer on the carrier substrate, a base insulating film is formed as a covering layer on the separating layer, and, for example, a thin film element layer including a semiconductor layer, an insulating layer, and an electrically conductive layer is formed on the base insulating film. Then, a primary transfer substrate made of, for example, glass or a resin such as an acrylic resin is bonded, with use of a water-soluble adhesive, to a surface of a flexible electronic device, which surface faces away from the carrier substrate, and the carrier substrate and the release layer are peeled off by, for example, irradiating a back surface of the carrier substrate with laser light. Then, a secondary transfer substrate (flexible substrate) made of, for example, a resin is bonded, with use of a non-water-soluble adhesive, to a surface from which the carrier substrate and the release layer have been peeled off, and the primary transfer substrate is peeled off by immersing an entire stack in water. Thus, a flexible electronic device is obtained in which, for example, a thin film element layer is provided on a flexible substrate via a base insulating film.

According to the flexible electronic device disclosed in Patent Literature 1, a patterned slit or hole is provided, during formation of the flexible electronic device, on at least part of the layers of the thin film element layer so that a crack is prevented. More specifically, according to Patent Literature 1, a patterned slit or hole is provided on, for example, a gate electrode. With the arrangement, internal stress of the gate electrode which internal stress is caused by bending of the device is released, and the internal stress is less concentrated. This (i) allows a crack to be less likely to appear in the gate electrode and (ii) prevents a crack which appears in the gate electrode from propagating to a surrounding area of the gate electrode.

### CITATION LIST

### Patent Literature

[Patent Literature 1]

Japanese Patent Application Publication Tokukai No. 2007-288080 (Publication date: Nov. 1, 2007)

### SUMMARY OF INVENTION

### Technical Problem

Note, however, that as described earlier, a crack frequently appears and easily propagates in an inorganic insulating layer, which is a brittle material. Therefore, a slit or a hole provided in a layer different from the covering layer is insufficiently effective in preventing a crack from propagating to the circuit formation region. A crack that advances to the circuit formation region may cause damage to a circuit, e.g., peel off an electrode. Moreover, a crack that advances to the circuit formation region may cause entry of moisture and/or oxygen into the circuit formation region from the crack. In a case where the circuit includes an EL element which is extremely vulnerable to moisture and oxygen, the EL element deteriorates due to entry of moisture and/or oxygen into the circuit formation region from a crack.

Meanwhile, in a case where an opening such as a slit is provided, by practically using a technique disclosed in Patent Literature 1, in a covering layer so that a flexible electronic device is more resistant to a crack, a support polyimide substrate is exposed via the opening.

Therefore, in a case where a covering layer has an opening such as a slit, the following problems may occur. Specifically, a support which is exposed via the opening may deteriorate in a later process, or the support in which a material that is less resistant to a chemical solution is used may cause elution of the material of the support, which is exposed to the chemical solution, and consequently cause contamination in later process. For example, in a case where polyimide is used in the support, the polyimide may be exposed via the opening and deteriorate, or may be eluted.

The present invention has been made in view of the above problems, and an object of the present invention is to provide (i) a flexible electronic device and (ii) a method of producing the flexible electronic device, the flexible electronic device and the method each being capable of preventing an advance of a crack in a covering layer without exposing a support.

### Solution to Problem

In order to attain the above object, a flexible electronic device in accordance with an aspect of the present invention includes: a support having flexibility; a covering layer which covers a surface of the support; a circuit provided on the covering layer; and at least one crack-guiding pattern continuously or discontinuously provided, in a region between an edge part of the covering layer and a circuit formation region in which the circuit is provided, so as to connect one end of the covering layer and another end of the covering layer, the at least one crack-guiding pattern being recessed and being configured to change a direction in which a crack having appeared in the edge part of the covering layer advances.

In order to attain the above object, a method of producing a flexible electronic device in accordance with an aspect of the present invention is a method of producing a flexible electronic device including a support having flexibility, a covering layer which covers a surface of the support, and a circuit provided on the covering layer, the method including the step of: continuously or discontinuously forming, in a region between an edge part of the covering layer and a circuit formation region in which the circuit is provided, at least one crack-guiding pattern so that the at least one recessed crack-guiding pattern connects one end of the covering layer and another end of the covering layer, the at least one crack-guiding pattern being recessed and being configured to change a direction in which a crack having appeared in the edge part of the covering layer advances.

### Advantageous Effects of Invention

According to an aspect of the present invention, it is possible to provide (i) a flexible electronic device and (ii) a method of producing the flexible electronic device, the flexible electronic device and the method each being capable of preventing an advance of a crack in a covering layer without exposing a support.

### BRIEF DESCRIPTION OF DRAWINGS

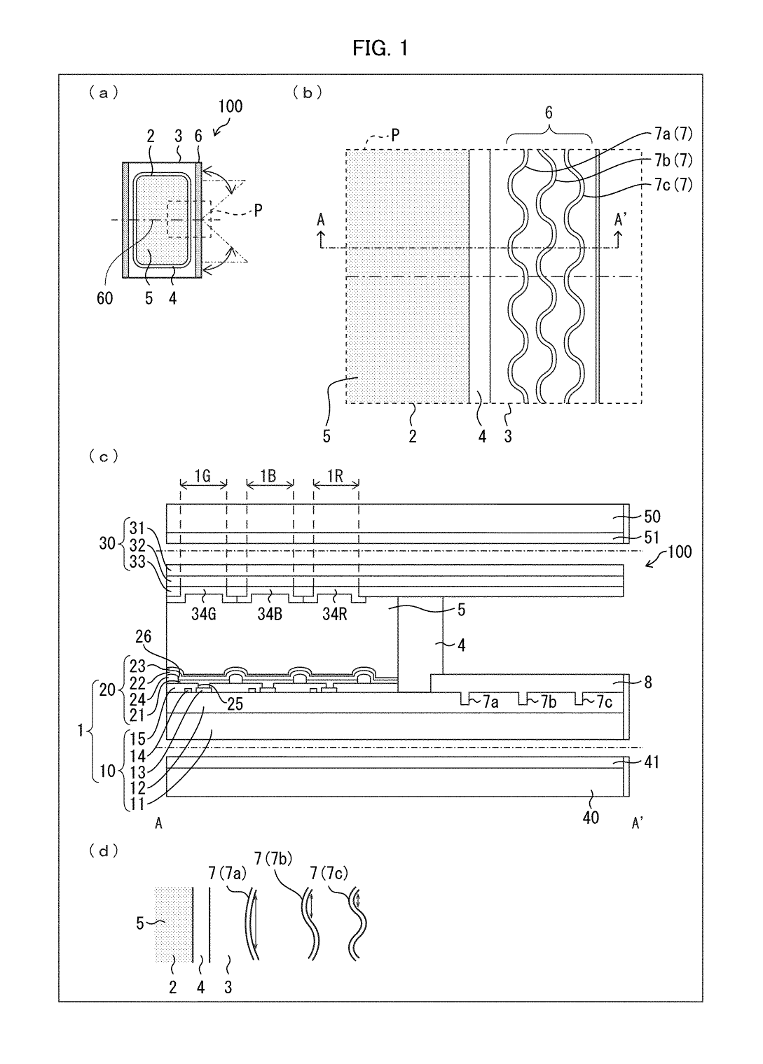

(a) of FIG. 1 is a plan view schematically illustrating a configuration of an organic EL display panel in accordance with Embodiment 1 of the present invention. (b) of FIG. 1 is an enlarged view illustrating a broken-line box P of (a) of FIG. 1. (c) of FIG. 1 is an exploded cross-sectional view illustrating a configuration of a main part of the organic EL display panel in accordance with Embodiment 1 from which organic EL display panel carrier substrates have not been peeled off. (d) of FIG. 1 is a plan view illustrating other examples of a wavy recessed pattern.

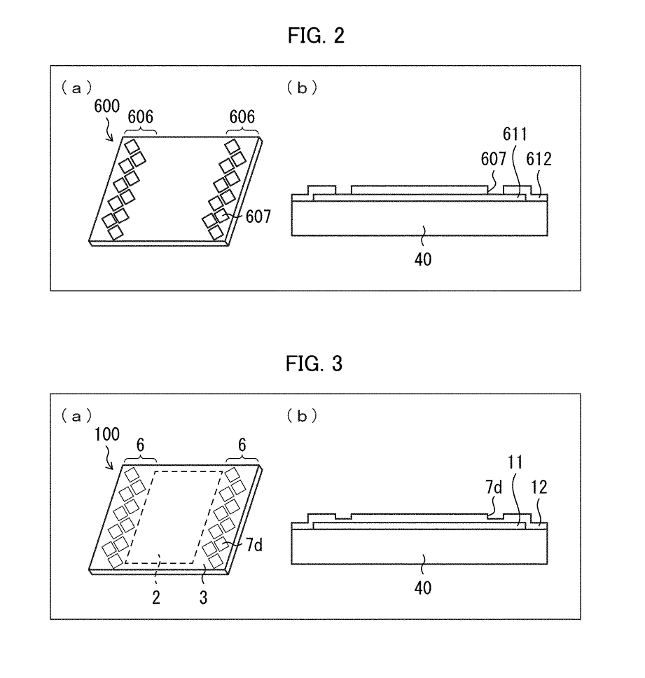

(a) of FIG. 2 is a perspective view illustrating a flexible organic EL display panel serving as Comparative Example. (b) of FIG. 2 is a cross-sectional view illustrating the flexible organic EL display panel serving as Comparative Example.

(a) of FIG. 3 is a perspective view illustrating another organic EL display panel in accordance with Embodiment 1 of the present invention. (b) of FIG. 3 is a cross-sectional view illustrating the organic EL display panel illustrated in (a) of FIG. 3.

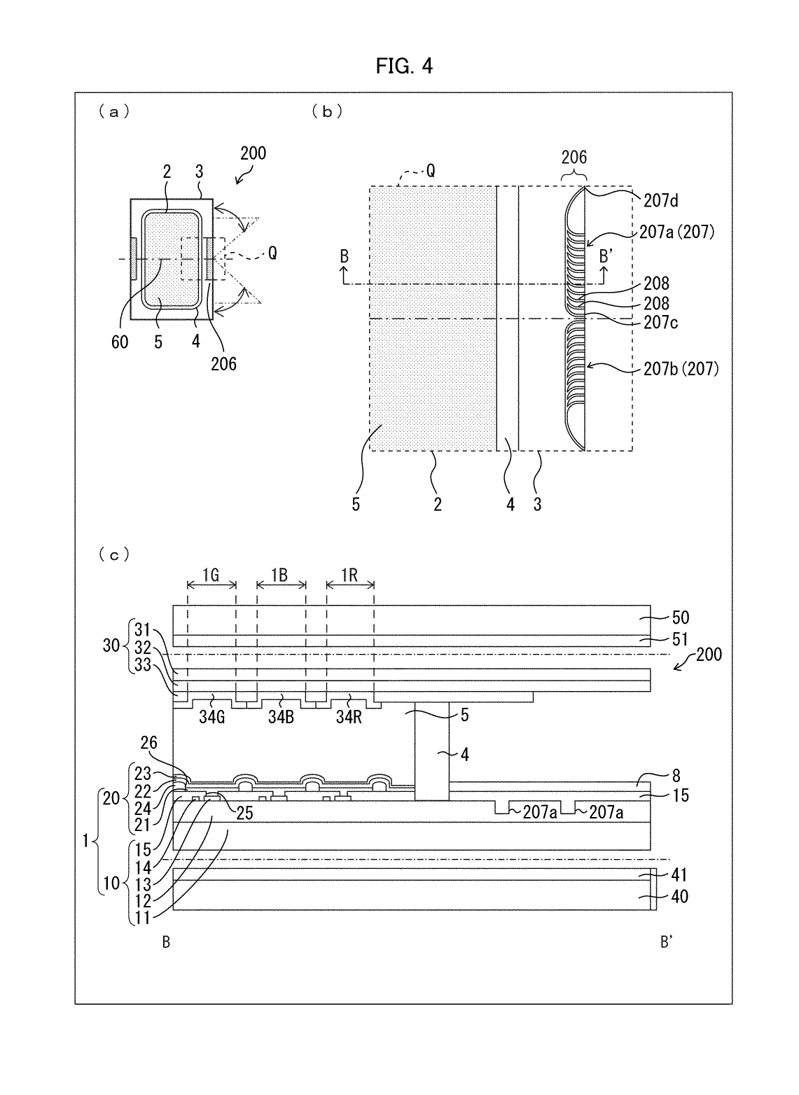

(a) of FIG. 4 is a plan view schematically illustrating a configuration of an organic EL display panel in accordance with Embodiment 2 of the present invention. (b) of FIG. 4 is an enlarged view illustrating a broken-line box Q of (a) of FIG. 4. (c) of FIG. 4 is an exploded cross-sectional view illustrating a configuration of a main part of the organic EL display panel in accordance with Embodiment 2 from which organic EL display panel carrier substrates have not been peeled off.

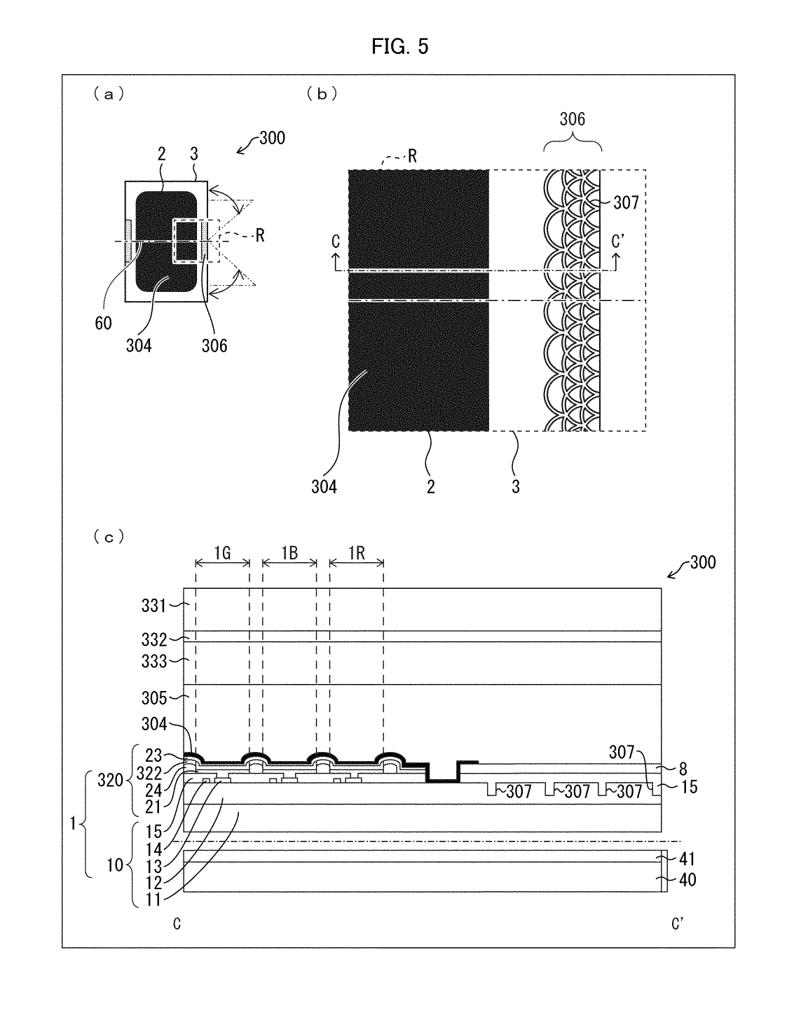

(a) of FIG. 5 is a plan view schematically illustrating a configuration of an organic EL display panel in accordance with Embodiment 3 of the present invention. (b) of FIG. 5 is an enlarged view illustrating a broken-line box R of (a) of FIG. 5. (c) of FIG. 5 is an exploded cross-sectional view illustrating a configuration of a main part of the organic EL display panel in accordance with Embodiment 3 from which organic EL display panel carrier substrates have not been peeled off.

(a) of FIG. 6 is a perspective view illustrating a conventional flexible electronic device. (b) of FIG. 6 is a cross-sectional view illustrating a configuration of a main part of the conventional flexible electronic device from which a carrier substrate has not been peeled.

(a) of FIG. 7 is a perspective view illustrating a state in which a conventional flexible electronic device is bent. (b) of FIG. 7 is an enlarged lateral view illustrating an arrangement of a surrounding area of a broken-line box of (a) of FIG. 7. (c) of FIG. 7 is a perspective view of a main part of the flexible electronic device, the perspective view illustrating a crack having appeared in the broken-line box of each of (a) and (b) of FIG. 7. (d) of FIG. 7 is a perspective view of the main part of the flexible electronic device, the perspective view illustrating how the crack advances in (a) and (b) of FIG. 7 in a case where the flexible electronic device is bent.

### DESCRIPTION OF EMBODIMENTS

### Embodiment 1

Embodiment 1 of the present invention will be specifically described below with reference to (a) through (c) of FIG. 1, and (a) and (b) of FIG. 3.

Note that the following description will take a flexible organic EL display panel as an example of a flexible electronic device in accordance with the present invention.

<Schematic Configuration of Organic EL Display Panel>

(a) of FIG. 1 is a plan view schematically illustrating a configuration of an organic EL display panel in accordance with Embodiment 1. (b) of FIG. 1 is an enlarged view illustrating a broken-line box P of (a) of FIG. 1. (c) of FIG. 1 is an exploded cross-sectional view illustrating a configuration of a main part of the organic EL display panel in accordance with Embodiment 1 from which organic EL display panel carrier substrates have not been peeled off. (d) of FIG. 1 is a plan view illustrating other examples of a wavy recessed pattern.

Note that (c) of FIG. 1 corresponds to an exploded cross-sectional view taken along a line A-A′ of an organic EL display panel 100, which is illustrated in (b) of FIG. 1 and from which the carrier substrates have not been peeled off. As such, (c) of FIG. 1 illustrates not only a configuration of a main part of the organic EL display panel 100 but also carrier substrates 40 and 50, and release layers 41 and 51 each used in a process for producing the organic EL display panel 100.

When viewed from above, the organic EL display panel 100 (flexible electronic device) has a display region 2 (circuit formation region) in which an image is to be displayed, and a non-display region 3 which surrounds the display region 2 (see (a) of FIG. 1). In the display region 2, for example, an organic EL element 20 (described later) is provided as a light-emitting element (electro-optic element).

The organic EL display panel 100 in accordance with Embodiment 1 includes an organic EL substrate 1 (flexible circuit substrate), a sealing substrate 30, a dam material 4, and a filling material 5 (see (c) of FIG. 1). The dam material 4 and the filling material 5 are provided between the organic EL substrate 1 and the sealing substrate 30. The organic EL substrate 1 includes a thin film transistor (TFT) substrate 10, the organic EL element 20, and an organic insulating film 8. The organic EL element 20 and the organic insulating film 8 are provided on the TFT substrate 10.

In the organic EL display panel 100, a support 11 having flexibility is used as a base material of the TFT substrate 10, and a counter support 31 having flexibility is used as a base material of the sealing substrate 30. This allows the organic EL display panel 100 to be flexible.

Hereinafter, in Embodiment 1, the organic EL display panel 100 has, as illustrated in (a) of FIG. 1, a bend part 60 as with an organic EL display panel 500 illustrated in each of (a) and (b) of FIG. 7. In (a) of FIG. 1, a center line along which to bend the bend part 60 is shown by a one-dot chain line which serves as a bend line.

For example, the organic EL display panel 100 in accordance with Embodiment 1 can be bent along the bend line shown by the one-dot chain line so that a display surface of the organic EL display panel 100 faces outward as shown by a two-dot chain line in (a) of FIG. 1. Alternatively, for example, the organic EL display panel 100 can be configured to be bendable so that the bend part has a curvature radius of 5 mm and so that surfaces that are opposite to each other across the bend line are parallel to each other.

(a) of FIG. 1 shows an example in which a single bend part 60 is provided at a center of a long side of the organic EL display panel 100 so as to be parallel to a short side of the organic EL display panel 100. Note, however, that the bend part 60 can also be provided so as to be parallel to a long side of the organic EL display panel 100. Alternatively, a plurality of bend parts 60 can be provided. In a case where a plurality of bend parts 60 are provided, the plurality of bend parts 60 can be bent in an identical direction or in respective different directions. For example, the organic EL display panel 100 which is formed so as to be bent into an accordion shape allows for compact storage of the organic EL display panel 100 which has a large area.

The following description assumes that, as described earlier, the organic EL display panel 100 is configured to have the bend part 60 and be bendable along the bend line. Note, however, that a configuration of the organic EL display panel 100 is not limited to such a configuration as described earlier. Alternatively, the organic EL display panel 100 can be configured to be bendable at any position.

(TFT Substrate 10)

The TFT substrate 10 (flexible circuit substrate) includes the support 11 which has an insulating property and flexibility, and a moistureproof layer 12 (covering layer) which is provided on the support 11.

In the display region 2, TFTs 13, wires 14, and a planarizing film 15 are mainly provided on the moistureproof layer 12. In the non-display region 3, the organic insulating film 8 is provided on the moistureproof layer 12.

The TFTs 13, the wires 14, and the organic EL element 20 (described later) constitute a circuit of the organic EL display panel 100. The moistureproof layer 12 covers a surface of the support 11 so as to cover the circuit.

The wires 14 include, for example, a plurality of gate lines, a plurality of source lines, and a plurality of power supply lines. Though not specifically illustrated in the drawings, a gate line and a source line are provided on respective different layers. When the wires 14 are viewed from above, in each of lattice regions surrounded by the wires 14, a red sub-pixel 1R, a green sub-pixel 1G, or a blue sub-pixel 1B is provided as a sub-pixel 1. In Embodiment 1, the red sub-pixel 1R, the green sub-pixel 1G, and the sub-pixel 1B which do not particularly need to be distinguished from one another are collectively simply referred to as sub-pixels 1. A set of the sub-pixels of red, green, and blue constitutes a single pixel.

Each of the sub-pixels 1 includes a corresponding TFT 13. The TFTs 13, which are connected to the wires 14, each cause a gate line to select a sub-pixel 1 to which a signal is to be supplied, cause a source line to determine an amount of electric charge to be supplied to the sub-pixel 1 thus selected, and cause an electric current to flow from a power supply line to the organic EL element 20.

The TFTs 13 and the wires 14 are covered with the planarizing film 15. The planarizing film 15 can be made of an insulating material such as an acrylic resin or a polyimide resin. The planarizing film 15 can have a thickness that is not particularly limited, provided that the planarizing film 15 can remove a level difference between respective upper surfaces of the TFTs 13 and the wires 14.

The moistureproof layer 12 covers the support 11 without exposing the surface of the support 11.

The support 11 can be a flexible film such as a polyimide film, or a flexible substrate such as a polyimide substrate. The moistureproof layer 12 can be a layer (inorganic insulating layer) made of an inorganic material such as silicon oxynitride (SiON), silicon nitride (SiN), silicon oxide (SiO), or aluminum oxide (Al2O3). The moistureproof layer 12 can be configured to have a thickness of, for example, 500 nm. Note, however, that the moistureproof layer 12 neither need to have any specific thickness nor need to be made of any specific material, provided that the moistureproof layer 12 can protect the support 11 from a chemical solution, moisture, or the like.

(Organic EL Element 20)

The organic EL element 20 includes first electrodes 21 (positive electrodes), an organic EL layer 22 which includes at least a light-emitting layer (not illustrated), and a second electrode 23 (negative electrode). The first electrodes 21, the organic EL layer 22, and the second electrode 23 are provided in this order from the TFT substrate 10 side. In Embodiment 1, layers provided between the first electrodes 21 and the second electrode 33 will be collectively referred to as the organic EL layer 22.

The first electrodes 21 are provided on the planarizing film 15. The first electrodes 21 each inject (supply) holes into the organic EL layer 22, and the second electrode 23 injects electrons into the organic EL layer 22. The first electrodes 21 are electrically connected to the respective TFTs 13 via respective contact holes 25 provided in the planarizing film 15.

Each of the first electrodes 21 has an edge part that is covered with an edge cover 24. The edge cover 24 is an insulating film which is made of, for example, a photosensitive resin. The edge cover 24 prevents, in an edge part of a first electrode 21, (i) electrode concentration and/or (ii) a short circuit which may occur between the first electrode 21 and the second electrode 23 due to the organic EL layer 22 which is made thin. The edge cover 24 also serves as a pixel-separating film which prevents an electric current from leaking out to an adjacent sub-pixel 1.

The edge cover 24 has an opening 26 for each of the sub-pixels 1. The first electrode 21 has a part which is exposed by the opening 26 and serves as a light-emitting region of a sub-pixel 1.

Embodiment 1 achieves a full-color image display by (i) vapor-depositing, on the entire display region 2, a light-emitting layer which emits white light and (ii) providing a color filter (CF) for each of the sub-pixels 1. The organic EL layer 22 is provided between the first electrodes 21 and the second electrode 23, and emits white light in accordance with a voltage to be applied across the first electrodes 21 and the second electrode 23.

The organic EL layer 22 includes, for example, a hole injection layer, a hole transfer layer, a light-emitting layer, an electron transfer layer, and an electron injection layer, which are provided in this order from the first electrode 21 side. Note that the organic EL layer 22 can include a single layer that has a plurality of functions. For example, the hole injection layer and the hole transfer layer can be replaced by a layer that functions as both the hole injection layer and the hole transfer. Alternatively, the electron injection layer and the electron transfer layer can be replaced by a layer that functions as both the electron injection layer and the electron transfer layer. Alternatively, between the respective layers of the organic EL layer 22, a carrier blocking layer can be provided as necessary.

In (c) of FIG. 1, each of the first electrodes 21 is an anode (pattern electrode, pixel electrode), and the second electrode 23 is a cathode (common electrode). Alternatively, each of the first electrodes 21 can be a cathode, and the second electrode 23 can be an anode. Note, however, that in such a case, the layers of the organic EL layer 22 are provided in a reversed order.

In a case where the organic EL display panel 100 is a top emission organic EL display panel that emits light from the sealing substrate 30 side as illustrated in (c) of FIG. 1, each of the first electrodes 21 is preferably made of a reflective electrode material, and the second electrode 23 is preferably made of a transparent or semitransparent light-transmitting electrode material.

Meanwhile, in a case where the organic EL display panel 100 is a bottom emission organic EL display panel that emits light from a back side of the support 11, the second electrode 23 is preferably made of a reflective electrode material, and each of the first electrodes 21 is preferably made of a transparent or semitransparent light-transmitting electrode material.

(Sealing Substrate 30)

The sealing substrate 30 includes the counter support 31 which has an insulating property and flexibility, a moistureproof layer (covering layer) 32 which covers the counter support 31, a black matrix (BM) 33, and color filters (CFs) 34R, 34G, and 34B.

The CF 34R, CF 34G, and CF 34B, which transmit red light, green light, and blue light, respectively, are provided on a surface of the counter support 31 which surface is on the TFT substrate 10 side. The BM 33 is provided at each of a boundary between the CF 34R and the CF 34G, a boundary between the CF 34G and the CF 34B, and a boundary between the CF 34B and the CF 34R.

This allows white light emitted from the organic EL element 20 to pass through the CF 34R, CF 34G, and CF 34B, so that red light, green light, and blue light are emitted in correspondence with the red sub-pixel 1R, the green sub-pixel 1G, and the blue sub-pixel 1B, respectively.

The counter support 31 can be made of, for example, a material of which the support 11 is made. The moistureproof layer 32 can be made of, for example, a material of which the moistureproof layer 12 is made. Specifically, the counter support 31 can be a flexible film such as a polyimide film, or a flexible substrate such as a polyimide substrate. The moistureproof layer 32 can be a layer made of an inorganic material such as silicon oxynitride (SiON).

The moistureproof layer 32 covers the counter support 31 without exposing a surface of the counter support 31. This makes it possible to prevent a chemical solution or moisture from adhering to the counter support 31. Therefore, even in a case where the counter support 31 is made of a base material made of a material that is less resistant to a chemical solution, such as polyimide, it is possible to prevent elution of the counter support 31 by the chemical solution and consequently prevent process contamination.

Though not illustrated in the drawings, the organic EL display panel 100 can include a touch panel and a hard coating which are provided via an adhesive layer on a surface of the counter support 31, which surface faces away from the moistureproof layer 32.

(Dam Material 4 and Filling Material 5)

The dam material 4 is provided between the TFT substrate 10 and the sealing substrate 30 so as to surround the display region 2 (see (c) of FIG. 1). That is, when viewed from above, the dam material 4 is provided along an outer circumference of the display region 2 (see (a) of FIG. 1). The dam material 4 is preferably made of a material having low moisture permeability.

The filling material 5 fills a region surrounded by the organic EL element 20 provided on the TFT substrate 10, the sealing substrate 30, and the dam material 4. The filling material 5 can be made of a material having low moisture permeability, or a material containing a desiccant and/or an oxygen absorber.

In a case where the filling material 5 is a non-curable filling material, the filling material 5 is present between the TFT substrate and the sealing substrate 30 in a liquid form. Meanwhile, in a case where the filling material 5 is a curable filling material and reliability of the organic EL element 20 can be achieved by causing the filling material 5 to sufficiently prevent moisture and/or oxygen from entering the organic EL element 20, the dam material 4 does not need to be provided. During the process for producing the organic EL display panel 100, after formation of the organic EL element 20, the filling material 5 is injected into a region surrounded by the dam material 4.

Note that it is possible to provide, between the second electrode 23 and the filling material 5, an organic layer (optical adjustment layer) (not illustrated) for adjusting an optical characteristic and/or an electrode protecting layer (not illustrated) for protecting the second electrode 23.

<Crack-Guiding Pattern 7>

When viewed from above, the organic EL display panel 100 has a rectangular shape (see (a) of FIG. 1). When viewed from above, the support 11 and the moistureproof layer 12 each also have a rectangular shape.

In the non-display region 3, the moistureproof layer 12 is provided with crack-guiding pattern arrangement regions (regions in each of which crack-guiding patterns are arranged) 6. The crack-guiding pattern arrangement regions 6 are provided so as to (i) be parallel to respective two long sides of the organic EL display panel 100 and (ii) connect short side edge parts of the organic EL display panel 100 which short side edge parts are opposite to each other. Each of the crack-guiding pattern arrangement regions 6 can be, for example, a region defined by an edge part of the organic EL display panel 100 (i.e., an edge part of the moistureproof layer 12) and a line which is 600 μm inner than the edge part of the organic EL display panel 100.

In each of the crack-guiding pattern arrangement regions 6, crack-guiding patterns 7 are provided (see (b) of FIG. 1). Each of the crack-guiding patterns 7 is recessed and is configured to prevent an advance of a crack, having appeared in an edge part of the moistureproof layer 12, to the display region 2 by changing a direction in which the crack advances.

According to the organic EL display panel 100 in accordance with Embodiment 1, in each of the crack-guiding pattern arrangement regions 6, three continuous crack-guiding patterns 7, each of which is wavy when viewed from above, are juxtaposed to each other astride the bend line. The crack-guiding patterns 7 are provided so as to (i) extend parallel to a long side of the organic EL display panel 100 and (ii) connect short side edge parts of the moistureproof layer 12 which short side edge parts are opposite to each other. Hereinafter, in a case where the three crack-guiding patterns 7 provided in each of the crack-guiding pattern arrangement regions 6 need to be distinguished from one another, the three crack-guiding patterns 7 will be distinguished from one another by being referred to as respective wavy recessed patterns 7a, 7b, and 7c.

Each of the crack-guiding patterns 7 is a recess which is provided on a surface of the moistureproof layer 12 so as not to penetrate the moistureproof layer 12 (see (c) of FIG. 1). For example, each of the crack-guiding patterns 7 can be configured to have a width of 10 μm and a depth of 250 nm in a direction in which a thickness of the moistureproof layer 12 extends. Each of the crack-guiding patterns 7 can also be configured to have a wave whose wavelength is 200 μm.

According to the organic EL display panel 100, in the non-display region 3, the crack-guiding patterns 7 are provided in the moistureproof layer 12. This makes it possible to prevent an advance of a crack, caused by bending of the support 11, from one of edge parts of the moistureproof layer 12 towards the display region 2 by guiding the crack to the other of the edge parts of the moistureproof layer 12 by changing a direction in which the crack advances.

Moreover, each of the crack-guiding patterns 7 is provided so as to face the bend line. In a case where each of the crack-guiding patterns 7 is thus provided in a part of the organic EL display panel 100, which part faces the bend line and to which part a crack easily advances due to stress concentration caused by bending of the organic EL display panel 100, it is possible to more reliably prevent an advance of the crack to the display region 2.

Moreover, each of the crack-guiding patterns 7 is continuously provided so as to connect the short side edge parts of the moistureproof layer 12 which short side edge parts are opposite to each other. This makes it possible to more reliably prevent an advance of a crack by changing a direction in which the crack advances. The crack is to advance from a long side edge part of the moistureproof layer 12 towards the display region 2 in a case where the organic EL display panel 100 is bent along the bend line, which is parallel to the short sides of the organic EL display panel 100.

That is, a crack advances so as to connect parts in which stress is concentrated. In a case where the organic EL display panel 100 is bent, stress is concentrated in the moistureproof layer 12 along the bend line. Therefore, in a case where no crack-guiding pattern 7 is provided, a crack advances along the bend line.

However, in a case where points at which stress is concentrated due to bending of the organic EL display panel 100 are optionally arranged by providing the crack-guiding patterns 7, each of which is recessed and is formed of a linear groove, it is possible to guide a crack in a direction in which the crack-guiding patterns 7 extend.

In the above case, a smallest possible angle that is formed between (a) a direction in which the crack advances and (b) a direction in which the crack-guiding patterns 7 are provided further allows the crack-guiding patterns 7 to effectively change the direction in which the crack advances.

The crack-guiding patterns 7 which are orthogonal to a direction in which a crack advances prevents points at which stress is concentrated from being continuously arranged so as to be parallel to the crack-guiding patterns 7. This makes it impossible to effectively change the direction in which the crack advances.

According to Embodiment 1, the wavy recessed patterns 7a, 7b, and 7c are provided as the crack-guiding patterns 7 in a direction orthogonal to the bend line. Each of the wavy recessed patterns 7a, 7b, and 7c is wavy and partially has a part with which the bend line forms a small angle. With the above part, it is possible to more reliably change a direction in which a crack advances.

Moreover, in order that none of inflection points (peaks) of the wavy recessed patterns 7a, 7b, and 7c coincide with each other in a direction in which the long sides of the organic EL display panel 100 extend, the wavy recessed patterns 7a, 7b, and 7c are provided so that positions of the inflection points are shifted in the direction in which the long sides of the organic EL display panel 100 extend. In other words, the wavy recessed patterns 7a, 7b, and 7c are provided so as to have respective waves that differ from each other in phase.

That is, as described above, in order to effectively achieve a crack-guiding function, it is desirable to parallel the bend line and the crack-guiding patterns 7 as much as possible.

Assume that each of the wavy recessed patterns 7a, 7b, and 7c is separated into inclined parts of waves (i.e., half-wavelength waves) and inflection points. In this case, the inclined parts have patterns that are more parallel to the bend line than linear patterns, whereas the inflection points are locally orthogonal to the bend line. That is, in view of respective tangent lines of an inclined part and an inflection point, the tangent line of the inclined part is more parallel to the bend line than that of the inflection point.

Therefore, in a case where only a single wavy crack-guiding pattern 7 is provided in each of the crack-guiding pattern arrangement regions 6, stress concentration in that crack-guiding pattern 7 does not effectively appears at an inflection point of the crack-guiding pattern 7. However, in a case where the positions of the inflection points of the wavy recessed patterns 7a, 7b, and 7c are shifted from each other as described earlier and the organic EL display panel 100 is considered as a group of regions each defined by straight lines that are parallel to the bend line, the organic EL display panel 100 has no region in which only an inflection point of a crack-guiding pattern 7 is present. In any one of the regions, not only an inflection point of a first crack-guiding pattern 7 but also an inclined part of a second crack-guiding pattern 7 different from the first crack-guiding pattern 7 are present.

Therefore, in a case where a plurality of wavy recessed patterns (the wavy recessed patterns 7a, 7b, and 7c), whose inflection points are positionally shifted from each other, are juxtaposed to each other as described earlier in each of the crack-guiding pattern arrangement regions 6 in a direction parallel to the bend line, the crack-guiding function can be complemented by the plurality of wavy recessed patterns. According to Embodiment 1, the crack-guiding patterns 7 are thus provided as patterns by which to complement the crack-guiding function.

As described earlier, according to Embodiment 1, since parts of the wavy recessed patterns 7a, 7b, and 7c, with each of which parts the bend line forms a small angle, are shifted from each other, those parts can be widely arranged so as to be parallel to a long side of the moistureproof layer 12. This makes it possible to more reliably change a direction in which a crack advances.

(b) of FIG. 1 shows an example in which the wavy recessed patterns 7a, 7b, and 7c, whose waves are identical in wavelength (cycle), are juxtaposed to each other so that the inflection points thereof differ from each other in position in the direction in which the long sides of the organic EL display panel 100 extend.

Note, however, that Embodiment 1 is not limited to the above example. Alternatively, by causing the waves of the wavy recessed patterns 7a, 7b, and 7c to differ in wavelength, the inflection points of the wavy recessed patterns 7a, 7b, and 7c can differ from each other in position in the direction in which the long sides of the organic EL display panel 100 extend. In this case, the wavy recessed patterns 7a, 7b, and 7c are preferably arranged such that the wavy recessed pattern 7a, 7b, or 7c which is closer to the display region 2 has a wave having a longer wavelength and the wavy recessed pattern 7a, 7b, or 7c which is farther from the display region 2 has a wave having a shorter wavelength. That is, the wavy recessed patterns 7a, 7b, and 7c are preferably arranged such that the wavy recessed pattern 7a (a first wavy recessed pattern) has a wave having a longest wavelength, the wavy recessed pattern 7b has a wave having a second-longest wavelength, and the wavy recessed pattern 7c (a second wavy recessed pattern) has a wave having a shortest wavelength (see (d) of FIG. 1). With the arrangement, (i) one of the wavy recessed patterns 7a, 7b, and 7c which one is closer to the display region 2 and (ii) the bend line form a greater angle, so that an inclined part between adjacent inflection points of the one of the wavy recessed patterns 7a, 7b, and 7c has a longer length. Therefore, since one of the wavy recessed patterns 7a, 7b, and 7c which one is closer to the display region 2 is longer in length for which to bend a crack (i.e., length of the inclined part), it is difficult for the crack to extend (advance) after a direction in which the crack advances is changed.

Note that (d) of FIG. 1 shows an example in which the wavy recessed patterns 7a, 7b, and 7c are arranged such that one of the wavy recessed patterns 7a, 7b, and 7c which one is closer to the display region 2 is longer in wavelength of a wave and one of the wavy recessed patterns 7a, 7b, and 7c which one is farther from the display region 2 is shorter in length of a wave. Note, however, that Embodiment 1 is not limited to the above example. Any one of the wavy recessed patterns only needs to be longer in wavelength of a wave than the other wavy recessed patterns which are farther from the display region 2 than the any one of the wavy recessed patterns. For example, the wavy recessed patterns 7a, 7b, and 7c can also be arranged such that the wavy recessed pattern 7b and the wavy recessed pattern 7c are equal in wavelength of a wave and the wavy recessed pattern 7a is longer in wavelength of a wave than the respective wavy recessed patterns 7b and 7c.

<Production Method>

An organic EL display panel 100 in accordance with Embodiment 1 is produced by the following method. Specifically, (i) an organic EL substrate 1 is formed on a carrier substrate 40 whose surface is provided with a release layer 41, (ii) a sealing substrate 30 is formed on a carrier substrate 50 whose surface is provided with a release layer 51, (iii) the organic EL substrate 1 is bonded to the sealing substrate 30, (iv) the release layer 41 and the carrier substrate 40 are peeled off from a support 11, and (v) the release layer 51 and the carrier substrate 50 are peeled off from a counter support 31. Note that the release layer 41 and the carrier substrate 40 are peeled off by using a laser ablation method or the like to irradiate the release layer 41 with light from the organic EL substrate 1 side. Similarly, the release layer 51 and the carrier substrate 50 are peeled off by using the laser ablation method or the like to irradiate the release layer 51 with light from the sealing substrate 30 side.

The following description will more specifically discuss the above method.

The step of producing the organic EL display panel 100 in accordance with Embodiment 1 includes (i) an organic EL substrate producing step, (ii) a sealing substrate producing step, (iii) a bonding step of bonding the organic EL substrate 1 to the sealing substrate 30, and (iv) a peeling step of peeling off the carrier substrates 40 and 50.

(Organic EL Substrate Producing Step)

First, the step of producing the organic EL substrate 1 will be described below.

In the step of producing the organic EL substrate 1, the release layer 41 is formed on the carrier substrate 40, which serves as a mother glass, so as to cover an entire surface of the carrier substrate 40. The carrier substrate 40 can be, for example, a glass substrate (carrier glass). The following description assumes that the carrier substrate 40 is a carrier glass. Note, however, that the carrier substrate is exemplified by various substrates each of which is conventionally used as a carrier substrate or a transfer substrate.

The carrier substrate 40 can be, for example, a plastic substrate made of a thermoplastic resin, a thermosetting resin, or the like. Examples of the plastic substrate include plastic substrates made of an acrylic resin, a polyethylene terephthalate (PET), an epoxy resin, and a phenol resin.

Note that the release layer 41 can be a well-known release layer that is conventionally used for transfer during production of a flexible electronic device.

The release layer 41 is exemplified by various well-known release layers such as a layer which is made of a material that is made lower in viscosity and adhesion by being heated, a layer which is made of, for example, hydrogenated amorphous silicon and is peeled off therefrom by desorbing hydrogen by photo irradiation, and a layer which is peeled off by use of a difference in film stress.

Examples of the release layer 41 include layers made of various oxide ceramics such as amorphous silicon, a silicon oxide, a titanium oxide, a zirconium oxide, and a lanthanum oxide; layers made of ceramics such as PZT, PLZT, PLLZT, and PBZT, and of dielectrics of these ceramics; layers made of nitride ceramics such as a silicon nitride, an aluminum nitride, and a titanium nitride; layers made of organic polymers; and layers made of alloys.

Next, on the release layer 41, the support 11 is formed as a mother base material. For example, by applying polyimide to the release layer 41 and baking the polyimide, the support 11 which is a polyimide layer (polyimide film) is formed on the release layer 41.

Next, on the surface of the support 11, a moistureproof layer 12 made of, for example, SiON is formed by a chemical vapor deposition (CVD) method, a spattering method, atomic layer deposition (ALD), or the like. A barrier film against moisture and an organic component is thus formed.

Subsequently, by applying a photosensitive resist (not illustrated) to the moistureproof layer 12 and using a photomask to subject the photosensitive resist to light exposure and development, an opening corresponding to a crack-guiding pattern 7 is formed in a region of the photosensitive resist which region corresponds to a non-display region 3 of each organic EL display panel 100.

Then, by using the photosensitive resist as a mask to half-etch (dry-etch or wet-etch) the moistureproof layer 12, a recessed linear pattern serving as a crack-guiding pattern 7 is formed on the moistureproof layer 12.

Then, in a region of the moistureproof layer 12 which region corresponds to a display region 2 of each organic EL display panel 100, TFTs 13, wires 14, a planarizing film 15, first electrodes 121, an edge cover 24, an organic EL layer 22, and a second electrode 23 are formed in this order by a well-known method. Meanwhile, in a region of the moistureproof layer 12 which region corresponds to the non-display region 3 of each organic EL display panel 100, an organic insulating film 8 is formed so as to planarize a surface of the moistureproof layer 12 in the non-display region 3. The organic EL substrate 1 is thus produced.

(Sealing Substrate Producing Step)

Next, the step of producing the sealing substrate 30 will be described below.

First, as with the organic EL substrate 1, the release layer 51 is formed on the carrier substrate 50 which serves as a mother glass, so as to cover an entire surface of the carrier substrate 50. Note that a release layer similar to the release layer 41 can be used as the release layer 51.

Next, as with the support 11, on the release layer 51, the counter support 31 is formed as a mother base material. For example, by applying a polyimide to the release layer 51 and baking the polyimide, the counter support 31 which is a polyimide layer (polyimide film) is formed on the release layer 51.

Next, on the surface of the counter support 31, a moistureproof layer 32 made of, for example, SiON is formed by the CVD method, the spattering method, the ALD, or the like. A barrier film containing moisture and an organic component is thus formed also on the surface of the counter support 31.

Next, for example, a thin chromium film or a resin film containing a black pigment is formed on the moistureproof layer 32, and then such a film is patterned by photolithography, so that a BM 33 is obtained. Subsequently, CFs 34R, 34G, and 34B are formed in corresponding voids of the BM 33 by patterning by a pigment dispersion method or the like. The sealing substrate 30 is thus produced.

(Bonding Step)

Next, the bonding step will be described below.

In the bonding step, a filling material 5 serving as a filler and a dam material 4 serving as a sealing material are applied to one of the organic EL substrate 1 and the sealing substrate 30. Note that the filling material 5 and the dam material 4 can be applied by a well-known method such as screen printing. Note also that the dam material 4 can alternatively be applied (drawn) with use of a dispenser. The dam material 4 is applied so as to surround the display region 2 of each organic EL display panel 100.

Next, in an atmosphere of an inert gas, the organic EL substrate 1 and the sealing substrate 30 are bonded to each other via the filling material 5 and the dam material 4, and at least the dam material 4 of the filling material 5 and the dam material 4 is cured so as to seal an organic EL element 20 in each organic EL display panel 100.

(Peeling Step)

Then, the carrier substrate 40 and the release layer 41 are peeled off at a boundary surface between the release layer 41 and the support 11 by irradiating the release layer 41 with laser light from the organic EL substrate 1 side. The carrier substrate 50 and the release layer 51 are peeled off at a boundary surface between the release layer 51 and the counter support 31 by irradiating the release layer 51 with laser light from the sealing substrate 30 side.

In Embodiment 1, laser light is used to (i) peel off the carrier substrate 40 and the release layer 41 and (ii) peel off the carrier substrate 50 and the release layer 51. Note, however, that light that is used to (i) peel off the carrier substrate 40 and the release layer 41 and (ii) peel off the carrier substrate 50 and the release layer 51 is not limited the laser light and can alternatively be flash lamp light.

(Other Steps)

The step of producing the organic EL display panel 100 can further include, after the step of peeling off the carrier substrate 50 and the release layer 51, a functional layer bonding step of bonding a functional layer (not illustrated) to the counter support 31.

The above step of bonding the functional layer is suitably carried out before the step of peeling off the carrier substrate 40 and the release layer 41 from the support 11.

In Embodiment 1, the functional layer which includes a touch panel (not illustrated) and a hard coating (not illustrated) is bonded to the sealing substrate 30 via an adhesive layer.

Note, however, that Embodiment 1 does not necessarily need to be arranged as above. For example, the functional layer which includes a hard coating and a polarizing plate instead of the touch panel and the hard coating can alternatively be bonded to the sealing substrate 30. Alternatively, the functional layer which includes, for example, a protecting film such as an organic film can be bonded to each of the organic EL substrate 1 and the sealing substrate 30. Such a functional layer serves as a supporting layer for each of the organic EL substrate 1 and the sealing substrate 30. For example, a polyimide film, which is used as each of the support 11 and the counter support 31, is thin and low in self-supporting property. Thus, each of the organic EL substrate 1 and the sealing substrate 30 is desirably provided with the functional layer which serves as a protecting layer or a supporting layer. Note, however, that a glass sheet, an acrylic sheet, or the like that is used to prevent a flaw in a product and/or to protect the product can also be used as the supporting layer, and the functional layer does not necessarily need to be provided.

Lastly, the mother base materials are cut, at given positions, into separate organic EL display panels 100.

During the cutting of the mother base materials as described above, a minute crack may appear in an edge part of the moistureproof layer 12. In a case where the organic EL display panel 100 in which a minute crack has appeared in the edge part of the moistureproof layer 12 is bent along the bend line, stress is concentrated in the moistureproof layer 12 along the bend line. In this case, the moistureproof layer 12 which is provided with no crack guiding pattern causes the minute crack to start advancing along the bend line so as to connect parts in which stress is concentrated. This causes the crack to extend to the display region 2, and consequently causes a problem of, for example, breakage in the organic EL element 20 provided on the moistureproof layer 12 in the display region 2.

### Comparative Example

Note that the moistureproof layer 12 which is provided with a through hole can prevent an advance of a crack in the moistureproof layer 12 in a case where the organic EL display panel 100 is bent. Note, however, that the moistureproof layer 12 which is provided with a through hole causes a surface of a support to be exposed via the through hole. Thus, the support which is made of, for example, polyimide as described earlier may cause a chemical solution having entered the support through the through hole of the moistureproof layer 12 during production of the organic EL display panel 100 to adhere to the support, and may consequently cause the polyimide to be eluted. The moistureproof layer 12 which is provided with a through hole is thus undesirable. The following description will specifically discuss the above problem with reference to (a) and (b) of FIG. 2, and (a) and (b) of FIG. 3.

(a) of FIG. 2 is a perspective view illustrating a flexible organic EL display panel serving as Comparative Example. (b) of FIG. 2 is a cross-sectional view illustrating the flexible organic EL display panel serving as Comparative Example.

(a) of FIG. 3 is a perspective view illustrating another organic EL display panel in accordance with Embodiment 1. (b) of FIG. 3 is a cross-sectional view illustrating the organic EL display panel illustrated in (a) of FIG. 3. Note that FIG. 3 shows an example of an organic EL display panel including, as a crack-guiding pattern 7, a plurality of quadrangular recessed patterns 7d that are discontinuously provided so as to connect two sides that are opposite to each other (e.g., long sides that are opposite to each other) in a non-display region 3 of a moistureproof layer 12. (a) of FIG. 3 shows an example in which diamond-shaped recessed patterns 7d are provided in the non-display region 3 of the moistureproof layer 12 in a zigzag pattern so as to be parallel to a side (e.g., a short side) of an organic EL display panel 600.

An advance of a crack, having appeared in a moistureproof layer 612 of an organic EL display panel 600, to a display region 2 can be prevented by the following method. According to the method, during production of the organic EL display panel 600, a crack-guiding pattern arrangement region 606 is formed in a vicinity of an edge part of the organic EL display panel 600 by providing the moistureproof layer 612, which is provided on a carrier substrate 40 so as to cover a support 611, with a plurality of through holes 607 serving as a crack-guiding pattern (see (a) and (b) of FIG. 2).

The above method makes it possible to prevent an advance of a crack having appeared in the edge part of the organic EL display panel 600, and consequently to prevent extension of the crack to the display region 2.

However, the moistureproof layer 612 which is provided with the plurality of through holes 607 causes a surface of the support 611 to be partially exposed. Thus, in a case where the support 611 is a support made of, for example, polyimide, during production of the organic EL display panel 600, a chemical solution enters the support through the plurality of through holes 607 and then adheres to the support, so that the polyimide is eluted.

In contrast, according to the organic EL display panel 100 in accordance with Embodiment 1, the crack-guiding pattern 7 of the moistureproof layer 12 is provided on a surface of the moistureproof layer 12 so as to have differences in level, i.e., is provided in a form of the plurality of recessed patterns 7d which do not penetrate the moistureproof layer 12.

It is therefore possible to prevent, without exposing a surface of the support 11, (i) an advance of a crack having appeared in an edge part of the moistureproof layer 12 and (ii) extension of the crack to the display region 2.

<Other Remarks>

The above description of Embodiment 1 assumes that the organic EL display panel 100 has a rectangular shape. Note, however, that the organic EL display panel 100 is not limited in shape and can also have a square shape.

The above description has taken, as an example, a configuration in which each of the three wavy recessed patterns 7a, 7b, and 7c is continuously provided so as to (i) connect the short side edge parts of the moistureproof layer 12 which short side edge parts are opposite to each other and (ii) be parallel to two long sides of the moistureproof layer 12. Note, however, that a configuration of the organic EL display panel 100 is not limited to such a configuration.

The organic EL display panel 100 can have not only three wavy recessed patterns but also one (1) wavy recessed pattern. The organic EL display panel 100 which has more wavy recessed patterns makes it possible to more reliably prevent an advance of a crack to the display region.

As illustrated in (b) of FIG. 1, the above description of Embodiment 1 assumes that each of the crack-guiding patterns 7 is a continuous pattern that connects edge parts of the organic EL display panel 100 which edge parts are opposite to each other across the bend line. Note, however, that each of the crack-guiding patterns 7 can be provided in a form of a continuous pattern, provided that a crack-guiding pattern 7 allows a minute crack having appeared in an edge part of the organic EL display panel 100, especially a minute crack having appeared in or near the bend part 60 and advancing in response to bending of the organic EL display panel 100, to advance towards another edge part of the organic EL display panel 100 in the non-display region 3 in a case where the organic EL display panel 100 is bent. Alternatively, each of the crack-guiding patterns 7 can be provided in a form of a discontinuous pattern as illustrated in (a) of FIG. 3. That is, according to Embodiment 1, each of the crack-guiding patterns 7 only needs to cause a minute crack having appeared in a long side edge part of the organic EL display panel 100 in or near the bend part 60 to advance towards a short side edge part of the organic EL display panel 100 in the non-display region 3 in a case where the organic EL display panel 100 is bent. This makes it possible to prevent an advance of a crack to the display region 2 in a case where the organic EL display panel 100 is bent along the bend line, which is parallel to a direction in which a short side of the organic EL display panel 100 extends.

The organic EL display panel 100 can also be configured such that not only the moistureproof layer 12 but also the moistureproof layer 32 is provided with the wavy recessed patterns 7a, 7b, and 7c. This makes it possible to prevent an advance of a crack in the moistureproof layer 32.

The organic EL display panel 100 can also be configured such that crack-guiding patterns 7 each of which is linear when viewed from above are provided instead of the wavy recessed patterns 7a, 7b, and 7c. Note, however, that since a crack-guiding pattern 7 is orthogonal to the bend line in such a configuration, the crack-guiding function is not effectively achieved. Thus, each of the crack-guiding patterns 7 desirably contains a component that is parallel or nearly parallel to the bend line.

Similarly, the wavy recessed patterns 7a, 7b, and 7c can alternatively be provided so that inflection points thereof in the direction in which the long sides of the organic EL display panel 100 extend are aligned in a direction in which the short sides of the organic EL display panel 100 extend. In such a case, however, the crack-guiding patterns 7 are locally orthogonal to the bend line at the inflection points. In view of this, the crack-guiding function is not effectively achieved on a line on which the inflection points are aligned.

Thus, the wavy recessed patterns 7a, 7b, and 7c are desirably provided so that positions of the inflection points thereof are shifted in the direction in which the long sides of the organic EL display panel 100 extend.

The above description of Embodiment 1 has taken, as an example, a case where each of the support 11 and the counter support 31 is, for example, a polyimide film. Note, however, that each of the support 11 and the counter support 31 can alternatively be a flexible substrate such as a polyimide substrate. In such a case, the carrier substrates 40 and 50, and the release layers 41 and 51 do not necessarily need to be provided, and the peeling step does not necessarily need to be carried out.

The above description of Embodiment 1 has taken, as an example, a case where each of the support 11 and the counter support 31 is a layer made of polyimide (i.e., a polyimide layer), such as a polyimide film or a polyimide substrate. Note, however, that each of the support 11 and the counter support 31 can be not only the layer made of polyimide but also a well-known flexible film substrate or plastic substrate that is made of, for example, polyethylene terephthalate (PET), polyethylene naphthalate (PEN), or an acrylic resin.

The above description of Embodiment 1 has taken, as an example, a case where the recessed linear patterns serving as the crack-guiding patterns 7 are formed in the moistureproof layer 12 by half-etching the moistureproof layer 12. Note, however, that the recessed linear patterns do not necessarily need to be formed by half-etching, and can alternatively be formed by nanoimprinting instead of half-etching. This makes it possible to form the crack-guiding patterns 7 in the moistureproof layer 12 at low cost.

The above description of Embodiment 1 has taken an organic EL display panel as an example of the flexible electronic device. Note, however, that the flexible electronic device can alternatively be an inorganic EL display panel. Specifically, the flexible electronic device can alternatively include, as the electro-optic element, a light-emitting element (i.e., an inorganic EL element) which replaces the organic EL element and in which electroluminescence of an inorganic light-emitting material is used.

The electro-optic element can alternatively be a liquid crystal element (liquid crystal layer). The flexible electronic device can alternatively be a display device in another display mode, such as a liquid crystal display device including a TFT and a liquid crystal element that serve as a circuit. The flexible electronic device can alternatively be an electrophoresis device including a circuit including an electrophoresis element. The flexible electronic device can alternatively be a light-emitting device including an LED chip that serves as a circuit, such as an LED illumination device. The flexible electronic device can alternatively be a card which includes an IC chip and a coil antenna that serves as a circuit and from/to which information is readable/writable, such as an IC tag or an IC card.

### Embodiment 2

Embodiment 2 of the present invention will be described below with reference to (a) through (c) of FIG. 4. Note that for convenience, members having functions identical to those of the respective members described in Embodiment 1 are given respective identical reference signs, and a description of those members is omitted.

(a) of FIG. 4 is a plan view schematically illustrating a configuration of an organic EL display panel in accordance with Embodiment 2. (b) of FIG. 4 is an enlarged view illustrating a broken-line box Q of (a) of FIG. 4. (c) of FIG. 4 is an exploded cross-sectional view illustrating a configuration of a main part of the organic EL display panel in accordance with Embodiment 2 from which organic EL display panel carrier substrates have not been peeled off.

Note that (c) of FIG. 4 corresponds to an exploded cross-sectional view taken along a line B-B′ of an organic EL display panel 200, which is illustrated in (b) of FIG. 4 and from which carrier substrates have not been peeled off. As such, (c) of FIG. 4 illustrates not only a configuration of a main part of the organic EL display panel 200 but also carrier substrates 40 and 50, and release layers 41 and 51 each used in a process for producing the organic EL display panel 200.

As illustrated in (a) through (c) of FIG. 4, the organic EL display panel 200 in accordance with Embodiment 2 is configured as in the case of the organic EL display panel 100 in accordance with Embodiment 1 except (i) that crack-guiding pattern arrangement regions 206 are provided only in or near a bend part 60, (ii) that each of crack-guiding patterns 207 has a plurality of branches 208, and (iii) that in a non-display region 3, a planarizing film 15 is provided on a moistureproof layer 12, and an organic insulating film 8 is provided on the planarizing film 15.

<Crack-Guiding Pattern>

In the non-display region 3 of the organic EL display panel 200, the moistureproof layer 12 is provided with the crack-guiding pattern arrangement regions 206, which are provided only in or near the bend part so as to be parallel to respective two long sides of the organic EL display panel 200 (see (a) of FIG. 4). Each of the crack-guiding pattern arrangement regions 206 can be provided in a region defined by (i) a long side edge part of the organic EL display panel 200 (i.e., an edge part of the moistureproof layer 12) and (ii) a straight line (imaginary line) that is 600 μm inner than the long side edge part and is 60 μm away from a dam material 4. In the above region, a crack-guiding pattern arrangement region 206 having a length of, for example, 10 mm can be provided so that the bend line of the bend part 60 is located at the center of the crack-guiding pattern arrangement region 206 in a direction parallel to the long sides of the organic EL display panel 200.

In each of the crack-guiding pattern arrangement regions 206, a crack-guiding pattern 207 is provided (see (b) of FIG. 4). The crack-guiding pattern 207 is recessed and is configured to prevent an advance of a crack, having appeared in an edge part of the moistureproof layer 12, to a display region 2 by changing a direction in which the crack advances.

The organic EL display panel 200 in accordance with Embodiment 2 includes the crack-guiding pattern 207, which is made up of two recessed patterns 207a and 207b each of which is gently curved when viewed from above and which are line symmetry with respect to the bend line.

The recessed pattern 207a has one end part 207c and the other end part 207d that face respective long side edge parts of the moistureproof layer 12. That is, the recessed pattern 207a is provided so as to connect the long side edge parts of the moistureproof layer 12.

The end part 207c faces the long side edge part of the moistureproof layer 12, which long side edge part is located in or near the bend part 60. Meanwhile, the end part 207d faces the long side edge part of the moistureproof layer 12, which long side edge part is away from the bend line.

The recessed pattern 207a branches into the plurality of branches 208 between the end part 207c and the end part 207d. Each of the plurality of branches 208 has an end part that faces the long side edge part of the moistureproof layer 12, which long side edge part is located in or near the bend part 60.

The recessed pattern 207a is a recess which is provided on a surface of the moistureproof layer 12 so as not to penetrate the moistureproof layer 12 (see (c) of FIG. 4). For example, the recessed pattern 207a can be configured to have a width of 5 μm and a depth of 250 nm in a direction in which a thickness of the moistureproof layer 12 extends. For example, adjacent branches 208 of the recessed pattern 207a can be provided at an interval of 30 μm, a branch 208 can be a curve having a curvature radius of 60 μm, and a branch 208 located in or near the end part 207d can be a curve having a curvature radius of 6700 μm. Moreover, a distance between the end part 207d and a branch 208 closest to the end part 207d can be, for example, 1000 μm.

In the non-display region 3, the planarizing film 15 is provided on the moistureproof layer 12 so as to fill the recessed pattern 207a. On the planarizing film 15, the organic insulating film 8 is provided.

A minute crack which has appeared in an edge part of the organic EL display panel 200 during, for example, division of the organic EL display panel 200 starts advancing towards the display region 2 in a case where the organic EL display panel 200 is bent.

According to the organic EL display panel 200 in accordance with Embodiment 2, the recessed pattern 207a has a plurality of end parts that are provided in or near the bend part 60, which is a part to be stressed by bending the organic EL display panel 200, so as to be parallel to an edge part of the moistureproof layer 12.

With the configuration, a minute crack having appeared in an edge part of the moistureproof layer 12 can be guided to another edge part of the moistureproof layer 12 by changing, at a relatively early stage in a process in which the crack advances, a direction in which the crack advances. This consequently makes it possible to prevent an advance of the crack towards the display region 2.

Moreover, according to the organic EL display panel 200 in accordance with Embodiment 2, the crack-guiding pattern arrangement regions 206 are provided on the moistureproof layer 12 only in or near the bend part 60. This allows a crack to extend only in or near the bend part 60.

### Embodiment 3

Embodiment 3 of the present invention will be discussed below with reference to (a) through (c) of FIG. 5. Note that for convenience, members having functions identical to those of the respective members described in Embodiments 1 and 2 are given respective identical reference signs, and a description of those members is omitted.

(a) of FIG. 5 is a plan view schematically illustrating a configuration of an organic EL display panel in accordance with Embodiment 3. (b) of FIG. 5 is an enlarged view illustrating a broken-line box R of (a) of FIG. 5. (c) of FIG. 5 is an exploded cross-sectional view illustrating a configuration of a main part of the organic EL display panel in accordance with Embodiment 3 from which organic EL display panel carrier substrates have not been peeled off.

Note that (c) of FIG. 5 corresponds to an exploded cross-sectional view taken along a line C-C′ of an organic EL display panel 300, which is illustrated in (b) of FIG. 5 and from which carrier substrates have not been peeled off. As such, (c) of FIG. 5 illustrates not only a configuration of a main part of the organic EL display panel 300 but also a carrier substrate 40 and a release layer 41 each used in a process for producing the organic EL display panel 300.

As illustrated in (a) through (c) of FIG. 5, the organic EL display panel 300 in accordance with Embodiment 3 is configured as in the case of the organic EL display panel 200 in accordance with Embodiment 2, except (i) that the organic EL display panel 300 includes a plurality of arc-shaped recessed patterns 307 which serve as a crack-guiding pattern 7 and each of which has an arc shape when viewed from above, (ii) that the organic EL display panel 300 includes a polarizing plate 331 and a touch panel 333 instead of the sealing substrate, (iii) that the organic EL display panel 300 includes an organic EL element 320 that differs from the organic EL element of Embodiment 2 in configuration, and (iv) that the organic EL display panel 300 has a sealing structure in which the organic EL element 320 is sealed with a sealing film 304 instead of the dam material 4 and the filling material 5.

<Schematic Configuration of Organic EL Display Panel>

The organic EL display panel 300 in accordance with Embodiment 3 includes the organic EL element 320 (see (c) of FIG. 5). The organic EL element 320 includes an organic EL layer 322 that has been formed by selective coating so that light in a different color is emitted for each sub-pixel. Specifically, the organic EL layer 322 includes (i) a region which corresponds to a red sub-pixel 1R and from which red light is emitted, (ii) a region which corresponds to a green sub-pixel 1G and from which green light is emitted, and (iii) a region which corresponds to a blue sub-pixel 1B and from which blue light is emitted.

The organic EL display panel 300 in accordance with Embodiment 3 thus includes the organic EL element 320 which has been formed by RGB selective coating. This makes it possible to carry out display with use of red light, green light, and blue light without using a color filter.

Moreover, in a display region 2 of the organic EL display panel 300, the sealing film 304 is provided so as to seal the organic EL element 320 between the sealing film 304 and a moistureproof layer 12. The organic EL display panel 300 which has such a film-sealing structure formed by the sealing film 304 makes it possible to prevent moisture and oxygen from entering the organic EL element 320, and consequently to prevent the organic EL element 320 from deteriorating. Note that the organic EL display panel 300 can include the sealing film 304 which is a film including a stack of an inorganic layer and an organic layer.

Moreover, the organic EL display panel 300 includes the polarizing plate 331 and the touch panel 333 instead of the sealing substrate. Specifically, (i) in the display region 2, the organic EL element 320 and the sealing film 304 are provided in this order on a TFT substrate 10, (ii) in a non-display region 3, an organic insulating film 8 is provided on the TFT substrate 10, and (iii) an adhesive layer 305, the touch panel 333, an adhesive layer 332, and the polarizing plate 331 are provided in this order on the sealing film 304 and the organic insulating film 8 (see (c) of FIG. 5).

The polarizing plate 331 can be a hard-coated polarizing plate 331 which has been surface-treated.

<Crack-Guiding Pattern>

In the non-display region 3 of the organic EL display panel 300, the moistureproof layer 12 is provided with crack-guiding pattern arrangement regions 306, which are provided only in or near a bend part so as to be parallel to two respective long sides of the organic EL display panel 300 (see (b) of FIG. 5). For example, each of the crack-guiding pattern arrangement regions 306 has a length of 10 mm in a direction parallel to a long side of the moistureproof layer 12, and can be provided in a region defined by (i) an edge part of the organic EL display panel 300 (i.e., and edge part of the moistureproof layer 12) and (ii) a straight line (imaginary line) which is 300 μm inner than the edge part.

In each of the crack-guiding pattern arrangement regions 306, a crack-guiding pattern is provided (see (b) of FIG. 5). The crack-guiding pattern is recessed and is configured to prevent an advance of a crack, having appeared in an edge part of the moistureproof layer 12, to the display region by changing a direction in which the crack advances.

The organic EL display panel 300 in accordance with Embodiment 3 includes the plurality of arc-shaped recessed patterns 307 which serve as the crack-guiding pattern and each of which has an arc shape when viewed from above. The plurality of arc-shaped recessed patterns 307 intersect each other, and the organic EL display panel 300 includes the crack-guiding pattern in which the plurality of arc-shaped recessed patterns 307 are joined together.

Each of the plurality of arc-shaped recessed patterns 307 is shaped so as to swell from the edge part side of the moistureproof layer 12 towards the display region 2 side of the moistureproof layer 12. An arc-shaped recessed pattern 307 has end parts some of which face respective long side edge parts of the moistureproof layer 12. That is, the arc-shaped recessed pattern 307 is provided so as to connect the long side edge parts of the moistureproof layer 12.

Each of the plurality of arc-shaped recessed patterns 307 is a recess which is provided on a surface of the moistureproof layer 12 so as not to penetrate the moistureproof layer 12 (see in (c) of FIG. 5). For example, each of the plurality of arc-shaped recessed patterns 307 can be configured to have a width of 5 μm and a depth of 250 nm in a direction in which a thickness of the moistureproof layer 12 extends.

In the non-display region 3, a planarizing film 15 is provided on the moistureproof layer 12 so as to fill the plurality of arc-shaped recessed patterns 307. On the planarizing film 15, an organic insulating film 8 is provided.

A minute crack which has appeared in an edge part of the organic EL display panel 300 during, for example, division of the organic EL display panels 300 starts advancing towards the display region 2 in a case where the organic EL display panels 300 is bent.

According to the organic EL display panel 300 in accordance with Embodiment 3, the arc-shaped recessed pattern 307 has a plurality of end parts that are provided in or near a bend part 60, which is a part to be stressed by bending the organic EL display panel 300, so as to be parallel to an edge part of the moistureproof layer 12.

With the configuration, a minute crack having appeared in an edge part of the moistureproof layer 12 can be guided to another edge part of the moistureproof layer 12 by changing, at a relatively early stage in a process in which the crack advances, a direction in which the crack advances. This consequently makes it possible to prevent an advance of the crack towards the display region 2.

Moreover, according to the organic EL display panel 300 in accordance with Embodiment 3, the crack-guiding pattern arrangement regions 306 are provided on the moistureproof layer 12 only in or near the bend part 60. This allows a crack to extend only in or near the bend part 60.

Moreover, according to the organic EL display panel 300 in accordance with Embodiment 3, since the plurality of arc-shaped recessed patterns 307 intersect each other, stress that causes an advance of a crack can be distributed. This allows a large crack to be less likely to appear.

Note that, as illustrated in (b) of FIG. 5, the plurality of arc-shaped recessed patterns 307 are preferably arranged to be (i) denser in a region that is relatively close to the display region 2 and (ii) less dense in a region that is relatively far from the display region 2.

With the arrangement, intersections of the plurality of arc-shaped recessed patterns 307 are spaced at longer distances in the region that is relatively close to the display region 2 than in the region that is relatively far from the display region 2. This causes a length for which to bend a crack (i.e., a length of an inclined part) to be longer in the region that is relatively close to the display region 2, so that it is difficult for the crack to extend (advance) after a direction in which the crack advances is changed by an arc-shaped recessed pattern 307 that is far from the display region 2.

(b) of FIG. 5 shows an example in which (i) arc-shaped recessed patterns 307 facing the display region 2 intersect each other only at their end parts, which are locally orthogonal to the bend line, and (ii) arc-shaped recessed patterns 307 which are different from the arc-shaped recessed patterns 307 facing the display region 2 intersect each other not only at their end parts but also at two other positions.

Note, however, that Embodiment 3 is not limited to the above example. Alternatively, the plurality of arc-shaped recessed patterns 307 can be arranged such that in a region closer to the display region 2, the plurality of arc-shaped recessed patterns 307 are less dense (i.e., arc-shaped recessed patterns 307 that are closer to the display region 2 less frequently cross each other at positions different from their end parts, and the intersections are spaced at longer distances).

[Recap]

A flexible electronic device (the organic EL display panel 100) in accordance with a first aspect of the present invention includes: a support (11) having flexibility; a covering layer (12, 32) which covers a surface of the support; a circuit (the TFTs 13, the wires 14, and the organic EL element 20) provided on the covering layer; and at least one crack-guiding pattern (the crack-guiding patterns 7, the wavy recessed patterns 7a, 7b, and 7c, the recessed patterns 7d, the recessed patterns 207a and 207b, or the arc-shaped recessed patterns 307) continuously or discontinuously provided, in a region between an edge part of the covering layer and a circuit formation region (the display region 2) in which the circuit is provided, so as to connect one end of the covering layer and another end of the covering layer, the at least one crack-guiding pattern being recessed and being configured to change a direction in which a crack having appeared in the edge part of the covering layer advances.

According to the above configuration, it is possible to prevent an advance of a crack having appeared in the edge part of the covering layer. This makes it possible to prevent extension of the crack to the circuit formation region, without exposing a surface of the support.

It is therefore possible to use, as the support, a polyimide substrate or the like that needs to be protected by the covering layer from moisture.

The flexible electronic device in accordance with a second aspect of the present invention can be configured such that, in the first aspect of the present invention, the flexible electronic device has a bend part (60); and the at least one crack-guiding pattern is provided so as to face the bend part.

In a case where the flexible electronic device is bent, stress caused by the bending is easily concentrated along the bend part, and therefore a crack easily advances along the bend part.

According to the above configuration, because the at least one crack-guiding pattern is provided so as to face the bend part in which stress is easily concentrated, it is possible to prevent an advance of a crack, which is to advance along the bend part, to the circuit formation region by changing a direction in which the crack advances.

The flexible electronic device in accordance with a third aspect of the present invention can be configured such that, in the first or second aspect of the present invention, the at least one crack-guiding pattern is at least one wavy recessed pattern (7a, 7b, and 7c) that is wavy when viewed from above.

According to the above configuration, since the at least one wavy recessed pattern is wavy, the wavy recessed pattern partially has a part with which a direction in which a crack advances forms a small angle. With the above part, it is possible to prevent an advance of a crack to the circuit formation region by more reliably changing a direction in which the crack advances.

The flexible electronic device in accordance with a fourth aspect of the present invention can be configured such that, in the third aspect of the present invention, the at least one crack-guiding pattern, which is the at least one wavy recessed pattern, includes a plurality of wavy recessed patterns; and the plurality of wavy recessed patterns have respective waves that differ from each other in phase or wavelength.

According to the above configuration, parts of each of the plurality of wavy recessed patterns, with each of which parts a direction in which a crack advances forms a small angle, can be widely arranged. This makes it possible to prevent an advance of a crack to the circuit formation region.

The flexible electronic device in accordance with a fifth aspect of the present invention can be configured such that, in the fourth aspect of the present invention, the respective waves of the plurality of wavy recessed patterns differ from each other in wavelength; and the plurality of wavy recessed patterns include a first wavy recessed pattern (wavy recessed pattern 7a) and a second wavy recessed pattern (wavy recessed patterns 7b and 7c) which is farther from the circuit formation region than the first wavy recessed pattern, the first wavy recessed pattern having a wave that has a greater wavelength than a wave of the second wavy recessed pattern.

According to the above configuration, the first wavy recessed pattern which is closer to the circuit formation region is (i) greater in angle formed between an inclined part and a direction in which a crack advances and (ii) longer in length of an inclined part between adjacent inflection points than the second wavy recessed pattern which is farther from the circuit formation region. Therefore, since the first wavy recessed pattern is longer in length for which to bend a crack (i.e., length of the inclined part) than the second wavy recessed pattern, it is difficult for the crack to extend (advance) after a direction in which the crack advances is changed by the second wavy recessed pattern.

The flexible electronic device in accordance with a sixth aspect of the present invention can be configured such that, in any one of the first through fifth aspects of the present invention, each of the support and the covering layer is quadrangular; and the at least one crack-guiding pattern is continuously provided so as to be parallel to the edge part of the covering layer and to connect sides of the covering layer which sides are opposite to each other.

According to the above configuration, since the at least one crack-guiding pattern is continuously provided so as to be parallel to the edge part of the covering layer and to connect sides of the covering layer which sides are opposite to each other, it is possible to more reliably prevent an advance of a crack by changing directions in which all cracks having appeared in the edge part advance.

The flexible electronic device in accordance with a seventh aspect of the present invention can be configured such that, in the second aspect of the present invention, the at least one crack-guiding pattern is provided only in or near the bend part.

With the above configuration, a crack can extend only in or near the bend part, in or near which the crack-guiding pattern is provided, after a direction in which the crack advances is changed by the at least one crack-guiding pattern.

The flexible electronic device in accordance with an eighth aspect of the present invention can be configured such that, in the seventh aspect of the present invention, the at least one crack-guiding pattern has a plurality of end parts in or near the edge part of the covering layer, in which edge part the bend part has an end part.

According to the above configuration, the at least one crack-guiding pattern has a plurality of end parts in an edge part of the covering layer, in which edge part the bend part has an end part, which is a part in which stress caused by bending of the flexible electronic device is easily concentrated.

With the configuration, an advance of a minute crack, having appeared in an edge part of the covering layer, in which edge part the bend part has an end part, to the circuit formation region can be prevented by changing, at a relatively early stage in a process in which the crack advances, a direction in which the crack advances.

The flexible electronic device in accordance with a ninth aspect of the present invention can be configured such that, in the eighth aspect of the present invention, the at least one crack-guiding pattern is a plurality of arc-shaped recessed patterns (307) each of which has an arc shape when viewed from above; and the plurality of arc-shaped recessed patterns intersect each other.

According to the above configuration, since the plurality of arc-shaped recessed patterns intersect each other, stress that occurs in the covering layer can be distributed. This allows a large crack to be less likely to occur.

The flexible electronic device in accordance with a tenth aspect of the present invention can be configured such that, in the ninth aspect of the present invention, the plurality of arc-shaped recessed patterns have fewer intersections in a region which is relatively close to the circuit formation region than in a region which is relatively far from the circuit formation region.

According to the above configuration, intersections of the plurality of arc-shaped recessed patterns are spaced at longer distances in the region that is relatively close to the circuit formation region than in the region that is relatively far from the circuit formation region. This causes a length for which to bend a crack (i.e., a length of an inclined part) to be longer as closer to the circuit formation region, so that it is difficult for the crack to extend (advance) after a direction in which the crack advances is changed.

A method of producing a flexible electronic device in accordance with an eleventh aspect of the present invention is a method of producing a flexible electronic device (the organic EL display panel 100) including a support (11) having flexibility, a covering layer (12) which covers a surface of the support, and a circuit (the TFTs 13, the wires 14. and the organic EL element 20) provided on the covering layer, the method including the step of: continuously or discontinuously forming, in a region (the display region 2) between an edge part of the covering layer and a circuit formation region in which the circuit is provided, at least one crack-guiding pattern (the crack-guiding patterns 7, the wavy recessed patterns 7a, 7b, and 7c, the recessed patterns 7d, the recessed patterns 207a and 207b, or the arc-shaped recessed patterns 307) so that the at least one recessed crack-guiding pattern connects one end of the covering layer and another end of the covering layer, the at least one crack-guiding pattern being recessed and being configured to change a direction in which a crack having appeared in the edge part of the covering layer advances.

According to the above method, it is possible to produce a flexible electronic device that can prevent extension of a crack having appeared in the edge part of the covering layer to the circuit formation region by preventing an advance of the crack, without exposing a surface of the support.

It is therefore possible to use, as the support, a polyimide substrate or the like that needs to be protected by the covering layer from moisture.

The method of producing the flexible electronic device in accordance with the present invention can be configured such that, in the eleventh aspect of the present invention, the at least one crack-guiding pattern is formed by half-etching the covering layer.

According to the above method, it is possible to form the at least one crack-guiding pattern with high accuracy.

The present invention is not limited to the embodiments, but can be altered by a skilled person in the art within the scope of the claims. The present invention also encompasses, in its technical scope, any embodiment derived by combining technical means disclosed in differing embodiments. Further, it is possible to form a new technical feature by combining the technical means disclosed in the respective embodiments.

### INDUSTRIAL APPLICABILITY

The present invention is applicable to a flexible electronic device such as a flexible organic EL display device.

### REFERENCE SIGNS LIST

2: Display region (circuit formation region)
7: Crack-guiding pattern
7a, 7b, 7c: Wavy recessed pattern (crack-guiding pattern)
7d: Recessed pattern (crack-guiding pattern)
11: Support
12, 32: Moistureproof layer (covering layer)
13: TFT (circuit)
14: Wire (circuit)
20, 320: Organic EL element (circuit)
31: Counter support (support)
60: Bend part
100, 200, 300: Organic EL display panel (flexible electronic device)
207a, 207b: Recessed pattern (crack-guiding pattern)
307: Arc-shaped recessed pattern (crack-guiding pattern)

1. A flexible electronic device comprising:
a support having flexibility;
a covering layer which covers a surface of the support;
a circuit provided on the covering layer; and
at least one crack-guiding pattern continuously or discontinuously provided, in a region between an edge part of the covering layer and a circuit formation region in which the circuit is provided, so as to connect one end of the covering layer and another end of the covering layer, the at least one crack-guiding pattern being recessed and being configured to change a direction in which a crack having appeared in the edge part of the covering layer advances.

2. The flexible electronic device as set forth in claim 1, wherein:
the flexible electronic device has a bend part; and
the at least one crack-guiding pattern is provided so as to face the bend part.

3. The flexible electronic device as set forth in claim 1, wherein the at least one crack-guiding pattern is at least one wavy recessed pattern that is wavy when viewed from above.

4. The flexible electronic device as set forth in claim 3, wherein:
the at least one crack-guiding pattern, which is the at least one wavy recessed pattern, comprises a plurality of wavy recessed patterns; and
the plurality of wavy recessed patterns have respective waves that differ from each other in phase or wavelength.

5. The flexible electronic device as set forth in claim 4, wherein:
the respective waves of the plurality of wavy recessed patterns differ from each other in wavelength; and
the plurality of wavy recessed patterns include a first wavy recessed pattern and a second wavy recessed pattern which is farther from the circuit formation region than the first wavy recessed pattern, the first wavy recessed pattern having a wave that has a greater wavelength than a wave of the second wavy recessed pattern.

6. The flexible electronic device as set forth in claim 1, wherein:
each of the support and the covering layer is quadrangular; and
the at least one crack-guiding pattern is continuously provided so as to be parallel to the edge part of the covering layer and to connect sides of the covering layer which sides are opposite to each other.

7. The flexible electronic device as set forth in claim 2, wherein the at least one crack-guiding pattern is provided only in or near the bend part.

8. The flexible electronic device as set forth in claim 7, wherein the at least one crack-guiding pattern has a plurality of end parts in or near the edge part of the covering layer, in which edge part the bend part has an end part.

9. The flexible electronic device as set forth in claim 8, wherein:
the at least one crack-guiding pattern is a plurality of arc-shaped recessed patterns each of which has an arc shape when viewed from above; and
the plurality of arc-shaped recessed patterns intersect each other.

10. The flexible electronic device as set forth in claim 9, wherein the plurality of arc-shaped recessed patterns have fewer intersections in a region which is relatively close to the circuit formation region than in a region which is relatively far from the circuit formation region.

11. A method of producing a flexible electronic device including a support having flexibility, a covering layer which covers a surface of the support, and a circuit provided on the covering layer,
the method comprising the step of:
continuously or discontinuously forming, in a region between an edge part of the covering layer and a circuit formation region in which the circuit is provided, at least one crack-guiding pattern so that the at least one recessed crack-guiding pattern connects one end of the covering layer and another end of the covering layer, the at least one crack-guiding pattern being recessed and being configured to change a direction in which a crack having appeared in the edge part of the covering layer advances.

12. The method as set forth in claim 11, wherein the at least one crack-guiding pattern is formed by half-etching the covering layer.
